(19) United States
(12) Patent Application Publication
(10) Pub. No.: US 2011/0056558 A1
(43) Pub. Date: Mar. 10, 2011

(54) SOLAR CELL

(75) Inventor: Chin-Yao Tsai, Tainan County (TW)

(73) Assignee: AURIA SOLAR CO., LTD., Tainan (TW)

(21) Appl. No.: 12/878,036

(22) Filed: Sep. 9, 2010

(30) Foreign Application Priority Data
Sep. 9, 2009 (TW) 98130397
Oct. 19, 2009 (TW) 98135272
Oct. 19, 2009 (TW) 98135273
Oct. 19, 2009 (TW) 98135275

(51) Int. Cl. H01L 31/04

(52) U.S. Cl. 136/258; 136/261

(57) ABSTRACT

A solar cell is provided, including a substrate, a first electrode, a second electrode, an n-type semiconductor layer and a p-type semiconductor layer. The first electrode is disposed on the substrate. The second electrode is disposed between the first electrode and the substrate. The n-type semiconductor layer is disposed between the first electrode and the second electrode. The material of the n-type semiconductor layer is microcrystalline silicon (μc-Si) or polysilicon. The p-type semiconductor layer is disposed between the first electrode and the n-type semiconductor layer.

### CROSS-REFERENCE TO RELATED APPLICATION

This application claims the priority benefits of Taiwan patent application serial no. 98130397, filed on Sep. 9, 2009, Taiwan application serial no. 98135275, filed on Oct. 19, 2009, Taiwan application serial no. 98135273, filed on Oct. 19, 2009 and Taiwan application serial no. 98135272, filed on Oct. 19, 2009. The entirety of each of the above-mentioned patent applications is hereby incorporated by reference herein and made a part of specification.

### BACKGROUND OF THE INVENTION

1. Field of the Invention

The present invention generally relates to a solar cell, and in particular, to a solar cell that can improve photoelectric conversion efficiency.

2. Description of Related Art

Solar energy is a clean, pollution-free and inexhaustible energy. Therefore, when problems of pollution and shortage of petroleum energy are encountered, how to effectively use the solar energy becomes a focus of attention. Since a solar cell can directly convert the solar energy into electric power, it becomes a development priority of using the solar energy.

A silicon-based solar cell is a commonly used solar cell in the art, and a principle of the silicon-based solar cell is to assemble a p-type semiconductor layer and an n-type semiconductor layer together, so as to form a p-n junction. When sunlight irradiates the semiconductor material with the p-n junction, energy carried by photons can excite electrons in the semiconductor material to generate electron-hole pairs. The electrons and the holes are all influenced by a built-in potential, wherein the holes move towards an electric field, and the electrons move towards an opposite direction. If the solar cell and a load are connected via a lead to form a loop, currents can flow through the load, thereby achieving a power generation principle of the solar cell. In general, a so-called “solar brick” refers to the solar photoelectric module applied to a roof or a floor.

### SUMMARY OF THE INVENTION

Accordingly, the present invention is directed to a solar cell with enhanced photoelectric conversion efficiency.

A solar cell of the present invention is provided, including a substrate, a first electrode, a second electrode, an n-type semiconductor layer and a p-type semiconductor layer. The first electrode is disposed on the substrate. The second electrode is disposed between the first electrode and the substrate. The n-type semiconductor layer is disposed between the first electrode and the second electrode. The material of the n-type semiconductor layer is microcrystalline silicon (μc-Si) or polysilicon. The p-type semiconductor layer is disposed between the first electrode and the n-type semiconductor layer.

According to the solar cell illustrated in an embodiment of the present invention, the solar cell further includes an intrinsic layer disposed between the p-type semiconductor layer and the n-type semiconductor layer.

According to the solar cell illustrated in an embodiment of the present invention, the material of the intrinsic layer is, for example, undoped amorphous silicon or undoped microcrystalline silicon (μc-Si).

According to the solar cell illustrated in an embodiment of the present invention, the material of the p-type semiconductor layer is, for example, amorphous silicon.

According to the solar cell illustrated in an embodiment of the present invention, the material of the first electrode is, for example, transport conductive oxide (TCO).

According to the solar cell illustrated in an embodiment of the present invention, the material of the second electrode is, for example, transport conductive oxide (TCO) or metal.

According to the solar cell illustrated in an embodiment of the present invention, the material of the substrate is, for example, glass.

As mentioned above, microcrystalline silicon (μc-Si) or polysilicon are utilized in the present invention serving as the material of the n-type semiconductor layer. Accordingly, photoelectric conversion efficiency of the solar cell can be enhanced.

In order to make the aforementioned and other features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 depicts, in a cross-sectional view, a solar cell according to an embodiment of the present invention.

FIG. 2 depicts, in a cross-sectional view, a solar cell according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

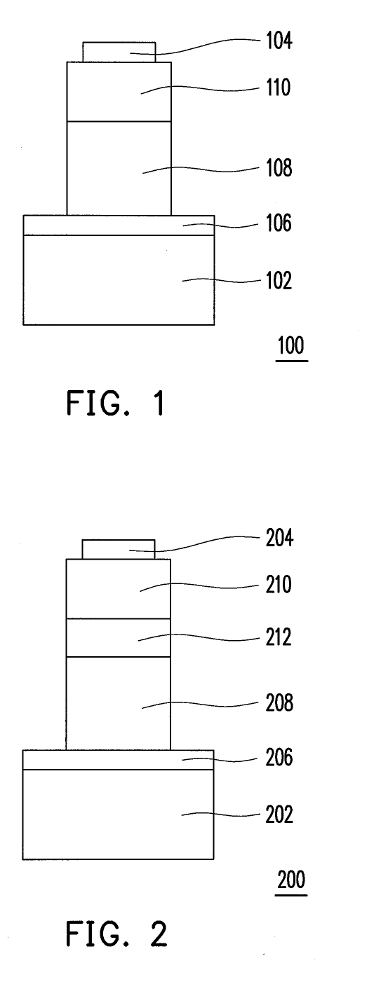

FIG. 1 depicts, in a cross-sectional view, a solar cell according to an embodiment of the present invention. Referring to FIG. 1, a solar cell 100 includes a substrate 102, an electrode 104, an electrode 106, an n-type semiconductor layer 108 and a p-type semiconductor layer 110.

The substrate 102 includes a transparent substrate, of which the material may be glass. The electrode 104 is disposed on the substrate 102.

The substrate 102 includes a ceramic substrate, and the material thereof may be oxide, nitride, boride or carbide, preferably aluminum oxide, magnesium oxide or calcium oxide. It is noted that since the substrate of the solar cell 100 is made of ceramic of which heat resistance and hardness are higher as compared with the substrate made of glass or plastics, the solar cell 100 having the ceramic substrate is suitable for material of a roof or a floor, that is the so-called solar brick.

The material of the electrode 104 is, for example, transport conductive oxide (TCO). The foregoing transport conductive oxide (TCO) can be aluminum doped zinc oxide (AZO), indium zinc oxide (IZO) or other transport conductive materials. The electrode 106 is disposed between the electrode 104 and the substrate 102. The material of the electrode 106 is, for example, transport conductive oxide (TCO) or metal. The foregoing transport conductive oxide (TCO) can be AZO, IZO or other transport conductive materials, and the foregoing metal can be silver, copper or other metals with both electric conductivity and high reflectivity.

The n-type semiconductor layer 108 is disposed between the electrode 104 and the electrode 106. The material of the n-type semiconductor layer 108 may be microcrystalline silicon (μc-Si) or polysilicon. The p-type semiconductor layer 110 is disposed between the electrode 104 and the n-type semiconductor layer 108. The material of the p-type semiconductor layer 110 is amorphous silicon, for instant.

The p-type semiconductor layer 110 is doped with material selected from the group consisting of elements in Group III in the periodic table, such as boron (B), aluminium (Al), gallium (Ga), indium (In) and thallium (Tl). The n-type semiconductor layer 108 is doped with material selected from the group consisting of elements in Group V in the periodic table, such as nitrogen (N), phosphorus (P), arsenic (As), antimony (Sb) and bismuth (Bi).

Among other things, the n-type semiconductor layer 108 made of microcrystalline silicon (μc-Si) benefits form that it is difficult for microcrystalline silicon (μc-Si) to bring photo-deterioration effect, and photoelectric conversion efficiency thereof is higher than that of crystalline silicon (c-Si). Thus, when sunlight irradiates the solar cell 100 from the direction of the electrode 104, the n-type semiconductor layer 108 made of microcrystalline silicon (μc-Si) can enhance the performance of the solar cell 100 effectively.

On the other hand, the n-type semiconductor layer 108 made of polysilicon benefits form simplified process and low cost, and photoelectric conversion efficiency thereof is higher than that of monocrystalline silicon. Thus, when sunlight irradiates the solar cell 100 from the direction of the electrode 104, the n-type semiconductor layer 108 made of polysilicon can enhance the performance of the solar cell 100 effectively.

Moreover, in other embodiments, an intrinsic layer can be further disposed between the p-type semiconductor layer and the n-type semiconductor layer.

FIG. 2 depicts, in a cross-sectional view, a solar cell according to another embodiment of the present invention. Referring to FIG. 2, a solar cell 200 includes a substrate 202, an electrode 204, an electrode 206, an n-type semiconductor layer 208, a p-type semiconductor layer 210 and an intrinsic layer 212. The electrode 204 is disposed on the substrate 202. The electrode 206 is disposed between the electrode 204 and the substrate 202. The n-type semiconductor layer 208 is disposed between the electrode 204 and the electrode 206. The p-type semiconductor layer 210 is disposed between the electrode 204 and the n-type semiconductor layer 208. The intrinsic layer 212 is disposed between the p-type semiconductor layer 210 and the n-type semiconductor layer 208. The material of the intrinsic layer 212 is, for example, undoped amorphous silicon or undoped microcrystalline silicon (μc-Si). The intrinsic layer 212 can serve as a major region for photons to generate electron-hole pairs.

Furthermore, the substrate 202, the electrode 204, the electrode 206, the n-type semiconductor layer 208 and the p-type semiconductor layer 210 are respectively made of the same materials as the substrate 102, the electrode 104, the electrode 106, then-type semiconductor layer 108 and the p-type semiconductor layer 110, and thus detailed descriptions of the same or like elements are omitted herein.

In view of the above, the present invention utilizes microcrystalline silicon (μc-Si) as the material of the n-type semiconductor layer. The photo-deterioration effect is not prone to occur in microcrystalline silicon (μc-Si), and the photoelectric conversion efficiency of microcrystalline silicon (μc-Si) is higher as compared with crystalline silicon (c-Si). Accordingly, when sunlight irradiates the solar cell of the present invention, the performance of the solar cell can be enhanced effectively.

In addition, the present invention utilizes polysilicon as the material of the n-type semiconductor layer. The photoelectric conversion efficiency of polysilicon is higher as compared with monocrystalline silicon. Accordingly, when sunlight irradiates the solar cell of the present invention, the performance of the solar cell can be enhanced effectively. Besides, since polysilicon has the advantage of low cost, the production cost of the solar cell can be reduces.

Further, the present invention utilizes ceramic as the material of the substrate in the solar cell. Since the heat resistance and hardness of ceramic are higher than those of glass or plastic, the solar cell with the ceramic substrate is much suitable for material of a roof or a floor (i.e. solar brick).

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar cell, comprising:
a substrate;
a first electrode, disposed on the substrate;
a second electrode, disposed between the first electrode and the substrate;
an n-type semiconductor layer, disposed between the first electrode and the second electrode, wherein a material of the n-type semiconductor layer is selected form one of microcrystalline silicon (μc-Si) and polysilicon; and
a p-type semiconductor layer, disposed between the first electrode and the n-type semiconductor layer.

2. The solar cell according to claim 1, further comprising an intrinsic layer disposed between the p-type semiconductor layer and the n-type semiconductor layer.

3. The solar cell according to claim 2, wherein a material of the intrinsic layer comprises undoped amorphous silicon or undoped microcrystalline silicon (μc-Si).

4. The solar cell according to claim 1, wherein a material of the p-type semiconductor layer comprises amorphous silicon.

5. The solar cell according to claim 1, wherein a material of the first electrode comprises transport conductive oxide (TCO).

6. The solar cell according to claim 1, wherein a material of the second electrode comprises transport conductive oxide (TCO) or metal.

7. The solar cell according to claim 1, wherein a material of the substrate comprises glass.

8. The solar cell according to claim 1, wherein a material of the substrate comprises ceramic.

9. The solar cell according to claim 8, wherein a material of the substrate comprises oxide, nitride, boride or carbide.
